(19) United States
(12) Patent Application Publication
(10) Pub. No.: US 2023/0416601 A1
(43) Pub. Date: Dec. 28, 2023

(54) CHIRAL POLYMERS AND USE THEREOF

(71) Applicant: Sumitomo Chemical Co., Ltd, Tokyo (JP)

(72) Inventors: Matthew Roberts, Godmanchester (GB); Przemek Gawel, Godmanchester (GB); Philip Benze, Godmanchester (GB); Jon Pillow, Godmanchester (GB); Michael Cass, Godmanchester (GB); Simon King, Godmanchester (GB); Martin Humphries, Godmanchester (GB); Thomas Fletcher, Godmanchester (GB)

(21) Appl. No.: 18/034,569

(22) PCT Filed: Oct. 29, 2021
(86) PCT No.: PCT/EP2021/080224

§ 371 Date: Apr. 28, 2023

(30) Foreign Application Priority Data
Oct. 30, 2020 (GB) 2017227.6

(51) Int. Cl. C09K 9/02; C08G 81/00; C08J 5/18; G02F 1/061; H04B 10/25

(52) U.S. Cl. CPC C09K 9/02; C08G 81/00; C08J 5/18; C09K 2211/1425; H04B 10/25; C08J 2387/00; C09K 2211/1466; G02F 1/061

(57) ABSTRACT

A chiral polymer comprising a repeat unit having a first planar group disposed in a first plane; a second planar group disposed in a second plane different from the first plane; a bond or group linking the first planar group and the second planar group; and a first divalent binding group linking the first planar group and the second planar group. The polymer may be used as the active material of an electrooptic modulator.

### BACKGROUND

The present disclosure relates to chiral polymers and use thereof in electro-optical modulators.

The rapid increase in recent years in both processor speeds and volume of data being generated requires a corresponding increase in bandwidth of data transmission means.

Electro-optic modulators (EOMs) for conversion of electrical signals to optical signals are known in which the EOM contains a material having a non-zero hyperpolarizability in the solid state, i.e. the refractive index of the material changes with applied electric field. An inorganic material known for use in electro-optic switching is lithium niobate (LiNbO₃).

Opto-electronic properties of dipolar (donor-acceptor) organic molecules with a strong ground state dipole moment are described in, for example, Dalton and Benight, ‘Theory guided design of organic electro-optic materials and devices’, Polymers, 2011, 3, 1325-1351.

Zyss and Ledoux ‘Nonlinear Optics in Multipolar Media: Theory and Experiments’, Chem. Rev., 1994, 94, 77-105 discloses octopolar organic non-linear molecules.

Strong hyperpolarizabilities have also been observed in solution in conjugated polymers without a donor-acceptor motif, for example polyphenanthrene as disclosed in Cleuvenbergen et al, ‘Record-high hyperpolarizabilities in conjugated polymers’ J. Mat. Chem C, 2014, 2, 4533 and polythiophene as disclosed in Deckers et al, Poly(3-alkylthiophene)s show unexpected second-order nonlinear optical response' Chem Commun, 2014, 50, 2741-43.

Verbiest et al ref: ‘Strong enhancement of nonlinear optical properties through supramolecular chirality’, Science, 1998, vol. 282, 913 discloses Langmuir-Blodgett films of a chiral helicene composed of supramolecular arrays of the molecules.

Ostroverkhov et al, “Second-harmonic generation in nonpolar chiral materials: relationship between molecular and macroscopic properties” J. Opt. Soc. Am. B, Vol. 18, No. 12, 2001, p. 1858-1865 discloses an oriented gas model for the second-order nonlinear optical response for optical second-harmonic generation in axially aligned nonlinear optical chromophores in chiral media.

### SUMMARY

In some embodiments, the present disclosure provides a chiral polymer comprising a repeat unit having a first planar group disposed in a first plane; a second planar group disposed in a second plane different from the first plane; a bond or group linking the first planar group and the second planar group; and a first divalent binding group linking the first planar group and the second planar group.

In some embodiments, the present disclosure provides an electrooptic modulator comprising a polymer film and electrodes for applying an electric field across the polymer film wherein the polymer film comprises a chiral polymer.

It will be understood that a chiral polymer as described herein is a polymer containing an enantiomeric excess of a chiral repeat unit. Likewise, a chiral monomer as described herein is a monomer containing an excess of an enantiomer of the monomer. A chiral monomer or polymer as described herein is optically active, e.g. it has a non-zero circular dichroism.

Optionally, the repeat unit is bound to adjacent repeat units by first and second bonds and wherein the angle between the first and second bonds is 180°±10°.

Optionally, the first and second bonds are collinear.

Optionally, repeat unit comprises a second divalent binding group.

Optionally, the angle between the first plane and the second plane is in the range of 1-89°.

Optionally, the first and second planar groups are, respectively, a first arylene or heteroarylene group and a second arylene or heteroarylene group and wherein each of the first and second arylene or heteroarylene groups is independently unsubstituted or substituted with one or more substituents.

Optionally, the first and second arylene or heteroarylene groups are linked by a direct bond.

Optionally, the direct bond is parallel to an axis of the polymer.

Optionally, the direct bond is perpendicular to an axis of the polymer.

Optionally, the repeat unit is selected from formulae (I)-(III):

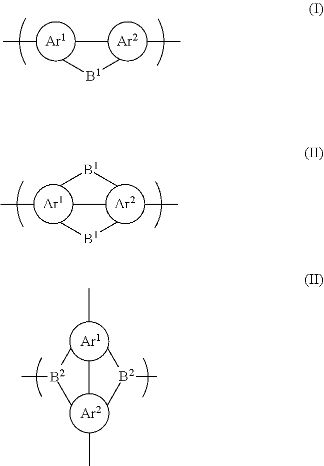

wherein Ar¹ is an arylene or heteroarylene group which is unsubstituted or substituted with one or more substituents; Ar² is an arylene or heteroarylene group which is unsubstituted or substituted with one or more substituents B¹ is a divalent binding group and B² in each occurrence is independently a divalent binding group

Optionally, the repeat unit is selected from formulae (Ia)-(IIIa):

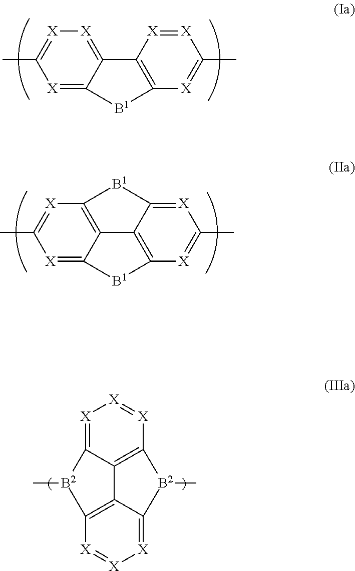

In some embodiments, the present disclosure provides a monomer of formula (I′), (II′) or (III′):

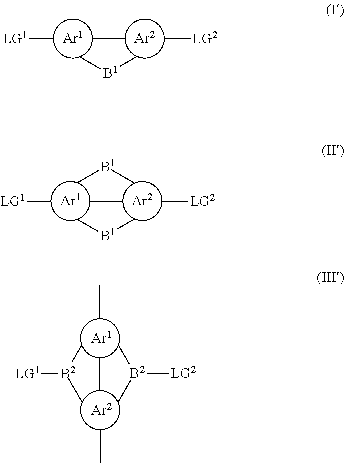

wherein Ar¹ is an arylene or heteroarylene group which is unsubstituted or substituted with one or more substituents and which is disposed in a first plane; Ar² is an arylene or heteroarylene group which is unsubstituted or substituted with one or more substituents and which is disposed in a second plane different from the first plane; B¹ in each occurrence is independently a divalent binding group; B² in each occurrence is independently a divalent binding group; LG¹ in each occurrence is independently a leaving group; and LG² in each occurrence is independently a leaving group.

Optionally, LG¹ in each occurrence is a halide, pseudohalide or boronic acid or ester bound to an aromatic carbon atom of Ar¹ or Ar²; and LG² is H bound to an N atom of B².

In some embodiments, the present disclosure provides a method of forming a polymer comprising polymerisation of a monomer as described herein.

In some embodiments, the present disclosure provides an electrooptic modulator comprising a polymer film wherein the polymer film comprises a chiral polymer.

Optionally, the chiral polymer comprises a repeat unit having a first planar group disposed in a first plane; a second planar group disposed in a second plane different from the first plane; a bond or group linking the first planar group and the second planar group; and a first divalent binding group linking the first planar group and the second planar group.

In some embodiments, the present disclosure provides an optical interconnect for transmitting data, comprising:
the electrooptic modulator as described herein; and
a light source coupled to an input of the electrooptic modulator;
wherein the electrooptic modulator is configured to modulate light emitted by the light source.

Optionally, the optical interconnect further comprises an optical fibre coupled at a first end to an output of the electrooptic modulator to receive the modulated light.

Optionally, the optical interconnect further comprises a photodetector coupled to a second end of the optical fibre.

In some embodiments, the present disclosure provides a system comprising:
the optical interconnect as described herein;
a first device; and
a second device;

wherein the optical interconnect is configured to transmit data from the first device to the second device.

Optionally, the system comprises a second optical interconnect as described herein, the second optical interconnect being configured to transmit data from the second device to the first device.

### DESCRIPTION OF DRAWINGS

The disclosed technology and accompanying figures describe some implementations of the disclosed technology.

FIG. 1 illustrates different possible conformations of polythiophene chains;

FIG. 2 illustrates a repeat unit according to some embodiments;

FIG. 3 schematically illustrates an electro-optic modulator according to some embodiments;

FIG. 4A schematically illustrates light input to an electro-optic modulator as shown in FIG. 3;

FIG. 4B schematically illustrates an electrical signal applied to an electro-optic modulator as shown in FIG. 3; and

FIG. 4C schematically illustrates light output from an electro-optic modulator as shown in FIG. 3.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers are may be present. References to a layer “on” another layer when used in this application means that the layers are in direct contact. References to a specific atom include any isotope of that atom unless specifically stated otherwise.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that a chiral polymer, i.e. a polymer in which the polymer chains contain an enantiomeric excess of a chiral repeat unit, may be used as an active material in an electro-optic modulator.

The present inventors have further found that the chirality of the repeat unit may be “locked in” to provide a thermodynamically stable enantiomer.

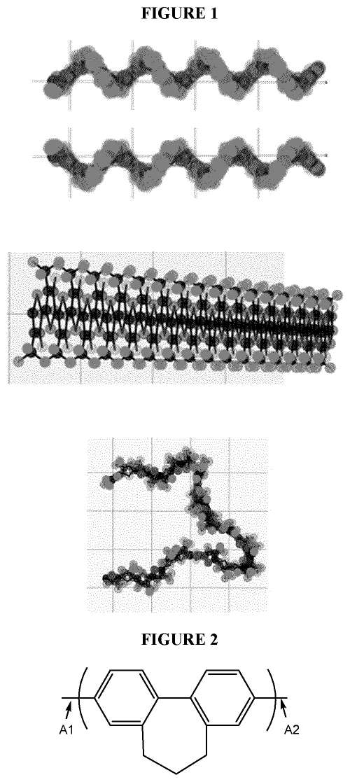

FIG. 1 schematically illustrates different configurations that a polymer chain may be able to adopt, depending on the values taken for the intermonomer twist angle. FIG. 1 illustrates polythiophene chains however it will be understood that this may be any chain of repeat units of an aromatic or heteroaromatic ring. Possible configurations include right-handed helices, left-handed helices and non-helical conformations, e.g. linear or other random, non-helical conformations. Due to the large number of unconstrained intermonomer twist angle possibilities, individual chains of poly(hetero)arylenes such as polythiophene may adopt a large number of such conformations, depending on the environment, each of which will give a contribution to the hyperpolarizability. Without wishing to be bound by any theory, it is believed that axially ordered films of such polymer chains in the solid state may result in a positive, negative or zero net electro-optic response (r33).

The present inventors have found that by providing a non-planar chiral repeat unit having a twist in the monomer structure, the resulting polymer chains can be constrained to adopting a static, helical conformation with non-zero chiral hyperpolarizability components. Enantiomeric excess in the chirality of the polymer chains can be achieved by polymerisation of such monomers having an excess of one of a (+) or (−) enantiomer.

The enantiomeric excess of the chiral repeat units may be at least 25%, more preferably at least 50%, yet more preferably 75% or 100%. The enantiomeric excess of the chiral repeat units may correspond directly with the enantiomeric excess of the corresponding monomers used to form the polymer.

It will be understood that chirality of polymers as described herein arises from the topology of the polymer chains, e.g. ratio of right-handed helical polymer chains : left-handed helical polymer chains which is not 1:1. As such, the repeat units described herein may or may not contain a stereogenic centre or axis of chirality.

Such an enantiomeric excess of the monomer to form the chiral repeat units may be achieved by a monomer synthesis including an enantioselective reaction step and/or a chiral resolution step.

The chiral resolution step may take place at any point in the monomer synthesis, including chiral resolution of a racemic mixture of any one of a starting material, a monomer intermediate or the monomer. Any suitable chiral resolution known to the skilled person may be used including, without limitation, crystallisation or reaction with an enantiomerically pure chiral reagent, separation of the resulting diasteromers.

Chiral polymers as described herein are suitably static, i.e. conversion of the chiral repeat unit to its optically active mirror image is not thermodynamically favourable at 25° C. in the solid state or in solution. Optionally, a chiral monomer as described herein has a racemisation energy of at least 2 kT, optionally at least 10 kT, at 298K.

A static configuration may be achieved by providing at least one binding group between first and second planar groups of a repeat unit of the polymer such that the most thermodynamically favourable conformation of the repeat unit is one in which the first and second planar groups lie in different planes, i.e. are twisted. It will be appreciated that such a binding group limits the freedom of movement of the first and second planar groups relative to one another, and preferably locks the first and second planar groups into a twisted configuration.

In some embodiments, the polymer is conjugated, i.e. repeat units in the polymer backbone are directly pi-conjugated to adjacent repeat units. Preferably, a carbon ring atom of an aromatic or heteroaromatic repeat unit of a repeat unit of the conjugated polymer is directly bound to a carbon ring atom of an aromatic or heteroaromatic repeat unit of an adjacent repeat unit.

In some embodiments, the polymer is non-conjugated. In these embodiments, the polymer may comprise repeat units which contain conjugated groups, e.g. aromatic or heteroaromatic groups, which are not conjugated to adjacent repeat units.

Preferably, the polystyrene-equivalent number-average molecular weight (Mn) measured by gel permeation chromatography of a polymer as described herein is in the range of about 1×10³ to 1×10⁸, and preferably 1×10⁴ to 5×10⁶. The polystyrene-equivalent weight-average molecular weight (Mw) of the polymer may be 1×10³ to 1×10⁸, and preferably 1×10⁴ to 1×10⁷.

### Repeat Units

In some embodiments, the twisted repeat unit of the polymer comprises a first arylene or heteroarylene group Ar¹ and a second arylene or heteroarylene group Ar² wherein Ar¹ and Ar² are linked by a single bond and are further linked by at least one binding group.

Optionally, the angle between the plane of Ar¹ and the plane of Ar² is 1-89°, and preferably as measured using quantum computing optimized monomer structures.

Quantum chemical computations were performed using Gaussian 09, Revision D.01 software. The structures were optimized using DFT model at B3LYP/6-31g(d) level of theory. Ground-state minima were confirmed based on the analysis of their analytical frequencies computed at the same level, which show no imaginary frequencies. Molecular static and frequency-dependent hyperpolarizabilities were computed on preoptimized geometries using DFT model at B3LYP/6-31g(d) level of theory and Polar job type and its options as implemented in Gaussian 09, Revision D.01.

Ar¹ and Ar² are each preferably selected from the group consisting of monocyclic or polycyclic aromatic or heteroaromatic groups. C₆₋₂₀ arylene groups are preferred, e.g. phenylene or naphthylene groups.

Ar¹ and Ar² may be the same or different, preferably the same.

The binding groups or groups may be selected so as to induce a twist between Ar¹ and Ar². This is illustrated in FIG. 2 in which the propylene binding group between phenylene groups A¹ and Ar² causes a twist between these groups.

The angle between the repeat unit's bonds A1 and A2 to adjacent repeat units is preferably 180°, as shown in FIG. 2. The range may be 180±35°, preferably 180±20°, more preferably 180°±10°

The bonds A1 and A2 may be parallel. Preferably, the bonds A1 and A2 are collinear, i.e. they lie on a common axis.

In some embodiments, the twisted repeat unit may be selected from formulae (I)-(III):

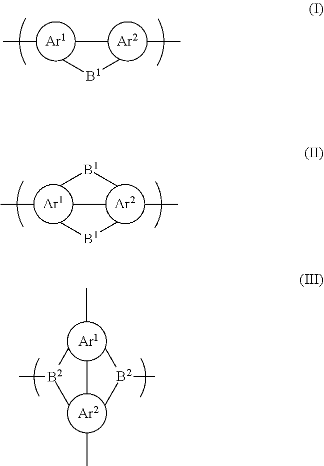

wherein B¹ in each occurrence is independently a divalent binding group and B² in each occurrence is independently a divalent binding group.

A¹ and Ar² are each independently unsubstituted or substituted with one or more substituents. Substituents may, independently in each occurrence, be selected from F; Cl; NO₂; CN; NH₂; OH; an aryl or heteroaryl group Ar³ which may be unsubstituted or substituted with one or more substituents; and C₁₋₁₂ alkyl wherein one or more non-adjacent C atoms may be replaced with O, S, NR⁶ wherein R⁶ is H or a substituent, CO or COO and one or more H atoms may be replaced with F.

An aryl or heteroaryl substituent of Ar¹ or Ar² may be unsubstituted or substituted with one or more substituents selected from F, Cl, CN, NO₂ or C₁₋₁₂ alkyl wherein one or more non-adjacent C atoms may be replaced with O, S, NR⁶, CO or COO and one or more H atoms may be replaced with F. The aryl or heteroaryl substituent may be a C6-20 aryl, e.g. phenyl or naphthyl; a monocyclic 5- or 6-membered heteroaromatic ring; or a fused heteroaromatic group.

In the case where R⁶ is a substituent, it is preferably a C₁₋₂₀ hydrocarbyl group.

Preferred groups Ar¹ and Ar² are phenylene and naphthalene.

In some embodiments, the chirality axis of formula (I) or (II), i.e. the bond between Ar¹ and Ar², is parallel to the polymer backbone.

In some embodiments, the chirality axis of formula (III) is perpendicular to the polymer backbone.

Preferably, B¹, together with Ar¹ and Ar², forms a 7 membered ring.

Exemplary B¹ groups include, without limitation:

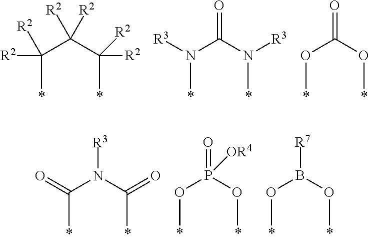

wherein R²-R⁴ in each occurrence is independently H or a substituent; R⁷ is a substituent, optionally a C₁₋₂₀ hydrocarbyl group; and * represents a bond to Ar¹ or Ar².

R² in each occurrence is preferably H; F; C₁₋₁₂ alkyl wherein one or more non-adjacent C atoms may be replaced with O, S, NR⁵, C=O or COO; or phenyl which may be unsubstituted or substituted with one or more substituents selected from C₁₋₁₂ alkyl wherein one or more non-adjacent C atoms may be replaced with O, S, NR⁵, C═O or COO.

R³ and R⁴ in each occurrence are preferably H or a C₁₋₂₀ hydrocarbyl group.

A C₁₋₂₀ hydrocarbyl group as described anywhere herein is preferably selected from C₁₋₁₂ alkyl; unsubstituted phenyl; and phenyl substituted with one or more C₁₋₁₂ alkyl groups.

Preferably, B², together with Ar¹ and Ar², forms a 7 membered ring. An exemplary binding group B² is:

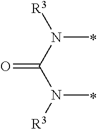

Preferably, Formulae (I), (II) and (III) are selected from, respectively, Formulae (Ia)-(IIIa):

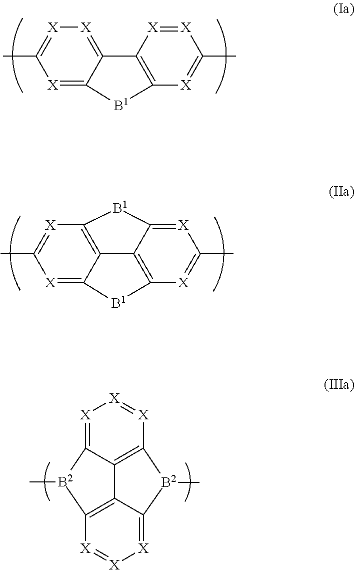

wherein X in each occurrence is CR¹ or N; R¹ in each occurrence is H or a substituent and substituents R¹ attached to adjacent carbon atoms may be linked to form an aromatic or non-aromatic ring. Optionally, non-H groups R¹, or a substituent of a ring formed by linkage of two R¹ groups, are selected from: F; Cl; NO₂; CN; NH₂; OH; Ar³; and C₁₋₁₂ alkyl wherein one or more non-adjacent C atoms may be replaced with O, S, NR⁶, CO or COO and one or more H atoms may be replaced with F. Ar³ is an aryl or heteroaryl group as described above.

Exemplary twisted repeat units are:

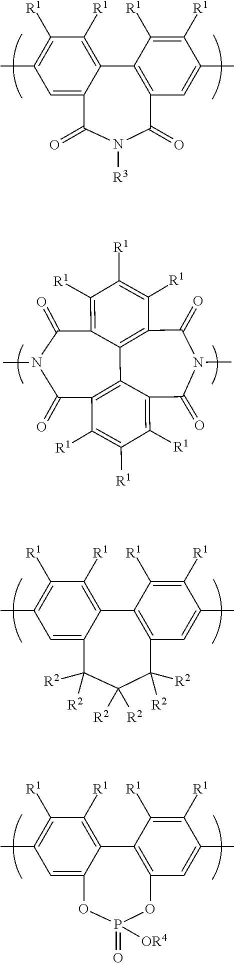

In some embodiments, A¹ and Ar² are the only two arylene or heteroarylene groups of the chiral repeat unit in the polymer backbone which are not in the same plane. In other embodiments, the chiral repeat unit may comprise more than two arylene or heteroarylene groups which are not in the same plane.

In some embodiments, the polymer is a homopolymer, e.g. a homopolymer comprising a repeat unit of formula (IIa) or (IIb).

In some embodiments, the polymer is a copolymer comprising a twisted repeat unit as described herein and one or more co-repeat units, e.g. an AB copolymer comprising a repeat unit of formula (IIa), (IIb) or (IIc) and a co-repeat unit. Preferably, the angle between the co-repeat unit's bonds to adjacent repeat units is 180°. Preferably, the co-repeat units' bonds to adjacent repeat units lie on the same axis.

A preferred co-repeat unit has formula (IV):

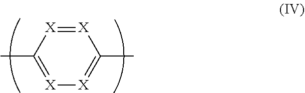

wherein X in each occurrence is N or CR¹ wherein R¹ is H or a substituent as described above. A particularly preferred co-repeat unit is 1,4-phenylene.

### Polymer Formation

Polymers described herein may be formed by any method known to the skilled person.

An exemplary method is polymerisation of one or more monomers for forming a homopolymer or copolymer, respectively, wherein each monomer has two halide leaving groups, e.g. Cl, Br or I, and including at least one monomer for forming a repeat unit as described herein, for example as disclosed in T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference;

Another exemplary method is polymerisation of one or more monomers having halide or pseudohalide (e.g. sulfonate) leaving groups and boronic acid or boronic ester leaving groups. In some embodiments, the monomers include one or more monomers substituted with two halide or pseudohalide groups and one or more monomers substituted with two boronic acid or boronic ester groups, wherein the monomers include at least one monomer for forming a repeat unit as described herein. In some embodiments, the monomers may comprise or consist of a monomer substituted with one halide or pseudohalide group and one boronic acid or boronic ester groups. Polymerisations according to this method are described in, for example, WO 00/53656, WO 2003/035796, and U.S. Pat. No. 5,777,070, the contents of which are incorporated herein by reference.

Another exemplary method is polymerisation of one or more monomers having halide or pseudohalide (e.g. sulfonate) leaving groups and an amino (NH or NH₂) group. In some embodiments, the monomers include one or more monomers substituted with two halide or pseudohalide groups and one or more monomers substituted with two amino groups, wherein the monomers include at least one monomer for forming a repeat unit as described herein. In some embodiments, the monomers may comprise or consist of a monomer substituted with one halide or pseudohalide group and one amino group. Polymerisations according to this method are described in, for example, U.S. Pat. No. 9,598,539, the contents of which are incorporated herein by reference.

### Polymer Film

A film comprising or consisting of a chiral helical polymer as described herein may be formed by deposition of a solution comprising the polymer. The solution comprises the polymer and any other materials of the film dissolved in one or more solvents.

The solution may be deposited onto a substrate followed by evaporation of the solvent(s). The solution may be deposited by any method known to the skilled person, e.g. spin-coating, dip-coating, roll-coating, spray coating, doctor blade coating, wire bar coating or slit coating.

Alignment of the polymer chains may be controlled during and/or after deposition of the solution. Methods to control alignment of the polymer chains include one or more of deposition by doctor blade coating; rubbing a deposited film at a temperature above its glass transition temperature; and alignment on a surface having surface features such as pores and/or channels or a surface patterning to cause alignment in a particular direction.

Preferably, a majority of the polymer chains of a polymer film, i.e. >50 mol % of the polymer chains of a polymer film are arranged parallel ±10° to an alignment axis of the polymer film.

The degree of alignment of the polymer film may be determined from the film's dichroic ratio.

The polymer film may consist of the chiral helical polymer in an enantiomeric excess or it may comprise one or more further materials, e.g. one or more insulating polymers.

### Applications

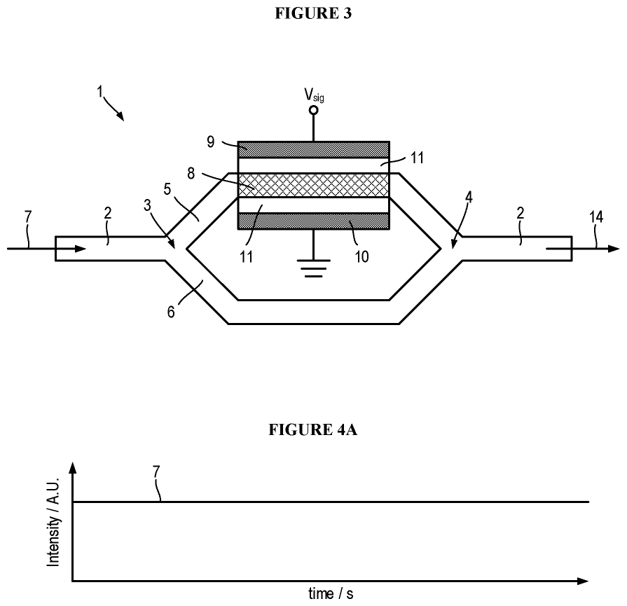

FIG. 3 illustrates an electrooptic modulator (EOM) 1 according to some embodiments of the present disclosure.

The EOM 1 comprises a waveguide 2 having an input 3, an output 4, a first path 5 extending between the input 3 and the output 4 and a second path 6 extending between the input 3 and the output 4. The input 3 and output 4 may each take the form of a bifurcated junction, although other structures serving to divide incident light 7 substantially equally between the first and second paths 5, 6 may be used instead of a bifurcated junction structure.

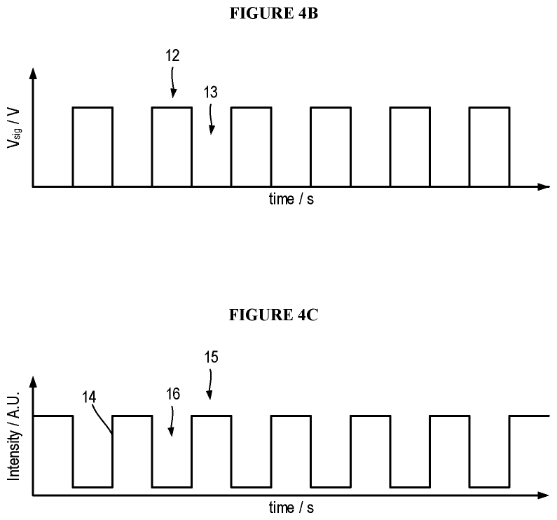

Referring also to FIG. 4A, the incident light 7 is substantially unmodulated and has a narrow bandwidth. Typically, the incident light 7 is supplied from a laser source, for example a laser diode, coupled to the waveguide 2. The incident light may be of any wavelength compatible with good transmission through the polymer film 8 and stability of the film. Typical communication wavelengths may be used such as, for example, wavebands including 600 nm, 850 nm, 1310 nm, 1550 nm and so forth.

The first path 5 comprises a polymer film 8 formed using a polymer as described herein and providing a section of waveguide through which light traversing the first path 5 passes. First and second electrodes 9, 10 are arranged to oppose one another across the polymer film 8 for applying an electric field across the polymer film 8. In some embodiments, the electrodes 9, may be directly applied to the polymer film 8. In some embodiments, one or both of the electrodes 9, 10 may be separated from the polymer film 8 by insulating layers 11. Insulating layers 11 may be formed of an organic or inorganic insulating material, and may serve to improve dielectric breakdown resistance between the electrodes 9, 10 and/or may serve as more conventional optical cladding for the waveguide segment provided by the polymer film 8. Optionally, the film has a thickness in the range of 100 nm-10 microns. Although illustrated in FIG. 3 as extending part-way between the input 3 and output 4, in some examples the polymer film 8 may extend between the input 3 and output 4. The electrodes 9, do not need to be co-extensive with the polymer film 8.

Preferably, polymer chains of the polymer film 8 are aligned at an angle of 45°±10° to the waveguide propagation axis.

Referring also to FIG. 4B, a time varying voltage signal V_{sig}(t) is applied across the electrodes 9, 10 to produce a time varying electric field E_{sig}(t) across the polymer film 8. Typically, the time varying voltage signal V_{sig}(t) is a binary signal switching between an on-state 12 and an off state 13. As consequence of the electro-optic coefficient r33 of the polymer film 8, the refractive index n of the polymer film 8 will also switch between a first value n₁ corresponding to the on-state 12 of the signal V_{sig}(t) and a second value n₂ corresponding to the off-state 13 of the signal V_{sig}(t).

Referring also to FIG. 4C, the length of the first and second paths 5, 6 are arranged so that when the polymer film 8 has the second value n₂, the light passing along the first and second paths 5, 6 has an optical path difference of n×λ, with n being an integer n≥0. The light interferes constructively and the output light 14 has a relatively high intensity state 15. By contrast, when the polymer film 8 has the first value n₁, the light passing along the first and second paths 5, 6 has an optical path difference of (n±1/2)Δλ. The light interferes destructively and the output light 14 has a relatively low intensity state 16.

Although illustrated in FIG. 4C with the first value n₁ corresponding to the low intensity state 16 and the second value n₂ corresponding to the high intensity state 15 such that the output light 14 signal is a binary signal which is inverse of the time varying voltage signal V_{sig}(t), in other examples the first value n1 may instead correspond to the high intensity state 15 whilst the second value n₂ corresponds to the low intensity state 16.

In other examples, the second path 6 may also include a polymer film 8 and corresponding electrodes 9, 10. The first and second paths 5, 6 may be arranged such that the first path 5 provides an optical path difference of (n+1/4)×λ, during the on-state 12 whilst the second path provides an optical path difference of (m−1/4)×λ. (with m an integer m≥0) for a total optical path difference which include a half wavelength ½λ.

In some examples, the input 3, output 4, and both paths 5, 6 may all be formed of the polymer film 8 to assist with index matching to waveguides providing incident light 7 and/or receiving output light 14.

An optical interconnect (not shown) for transmitting data may include the EOM 1. A light source (not shown) can be coupled to input 3 of the EOM to provide incident light 7. The light source (not shown) may be any suitable light source such as, for example, a light-emitting diode (LED), and organic light emitting diode (OLED), a laser diode, an organic laser diode and so forth. The light source (not shown) may be directly coupled to the input 3 of the EOM 1, or may be coupled to the EOM 1 via one of more optical fibres (not shown) or other waveguides. The EOM 1 can be used to modulate the light 7 emitted by the light source as described hereinbefore. The optical interconnect (not shown) may also include an optical fibre (not shown), or any other suitable waveguide structure, coupled to the output 4 to receive the modulated output light 14. The optical interconnect (not shown) may also include a photodetector (not shown) coupled to an opposite end of the optical fibre (or other waveguide structure) to receive the modulated output light 14. The photodetector (not shown) may be of any suitable type, for example a photodiode, but should have a bandwidth (response time) at least as fast as the intended modulation rate of the EOM 1.

In some examples of optical interconnects (not shown), the second of waveguide 2 leading up to the input 3 may be coupled to the light source (not shown) without any intervening optical fibre (not shown). Additionally or alternatively, the section of waveguide 2 leading away from the output 4 may extend up to the photodetector (not shown) without any intervening optical fibre (not shown) or a transition to a separate waveguide structure. Extension of the sections of waveguide 2 may be preferred for short range interconnects, whereas longer interconnects may be provided more easily using optical fibres (not shown).

Optical interconnects (not shown) including the EOM 1 may be configured to connect between a first device (not shown) and a second device (not shown), in order to transmit data from the first device to the second device or vice versa. A second optical interconnect may optionally transmit data in the reverse direction.

The first and second devices (not shown) may be any type of data processing devices, and do not need to be of the same type. Optical interconnects (not shown) including the EOM 1 may be configured to connect between a first device (not shown) and a second device (not shown) at a range of scales, for example, between two entirely separate computers, between internal components of a single computer (e.g. connecting a digital electronic processor to a memory, hard disc and so forth), between components mounted to the same circuit board, or even between components formed from a single semiconductor wafer. For example, an optical interconnect (not shown) may connect a pair of servers, a pair of racks within a server, a digital electronic processor to memory or other computer component, between a pair of cores of a multi-core digital electronic processor and so forth.

### EXAMPLES

### Chiral Intermediate Formation

A racemic mixture of P and M may be crystallised with chiral auxiliary, such as quinine as a as described in J. Org. Chem. 2002, 67, 3479-3486, the contents of which are incorporated herein by reference, to form a diasteromeric salt which may be separated to give a pure enantiomer.

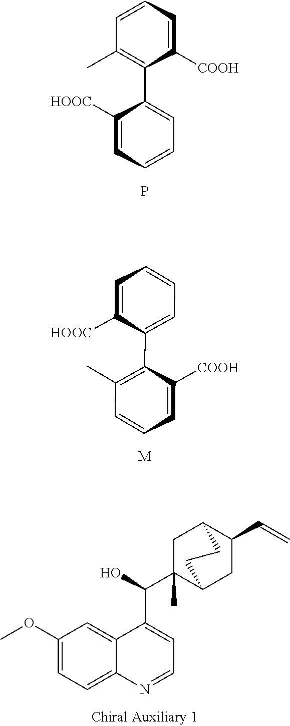

A chiral monomer as described herein containing a binaphthyl group may be formed from a BINOL, as illustrated in General Scheme 1, in which B, together with the hydroxyl groups of the binol starting material, forms a binding group:

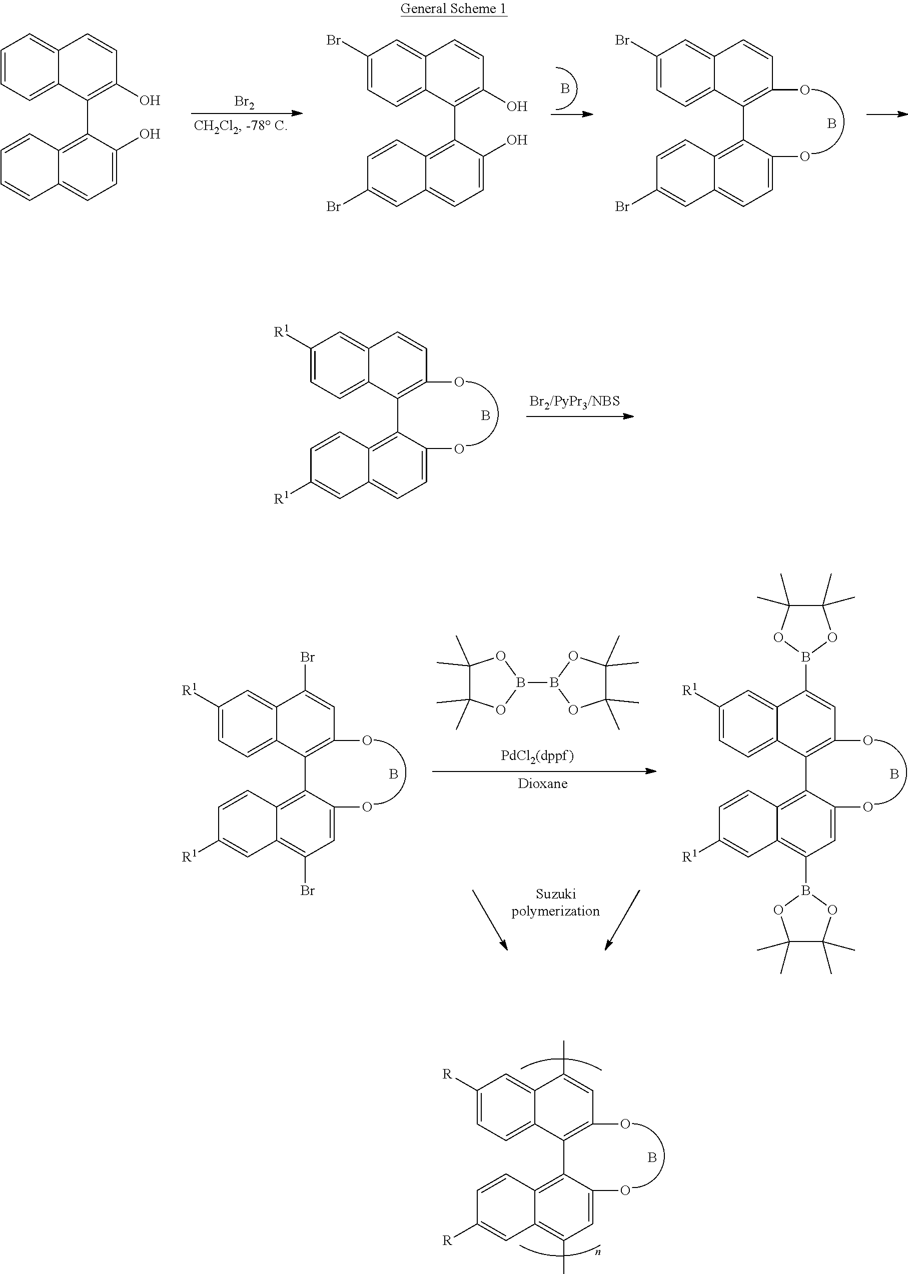

Specific examples of General Scheme 1 are shown in Scheme 1A and Scheme 1B:

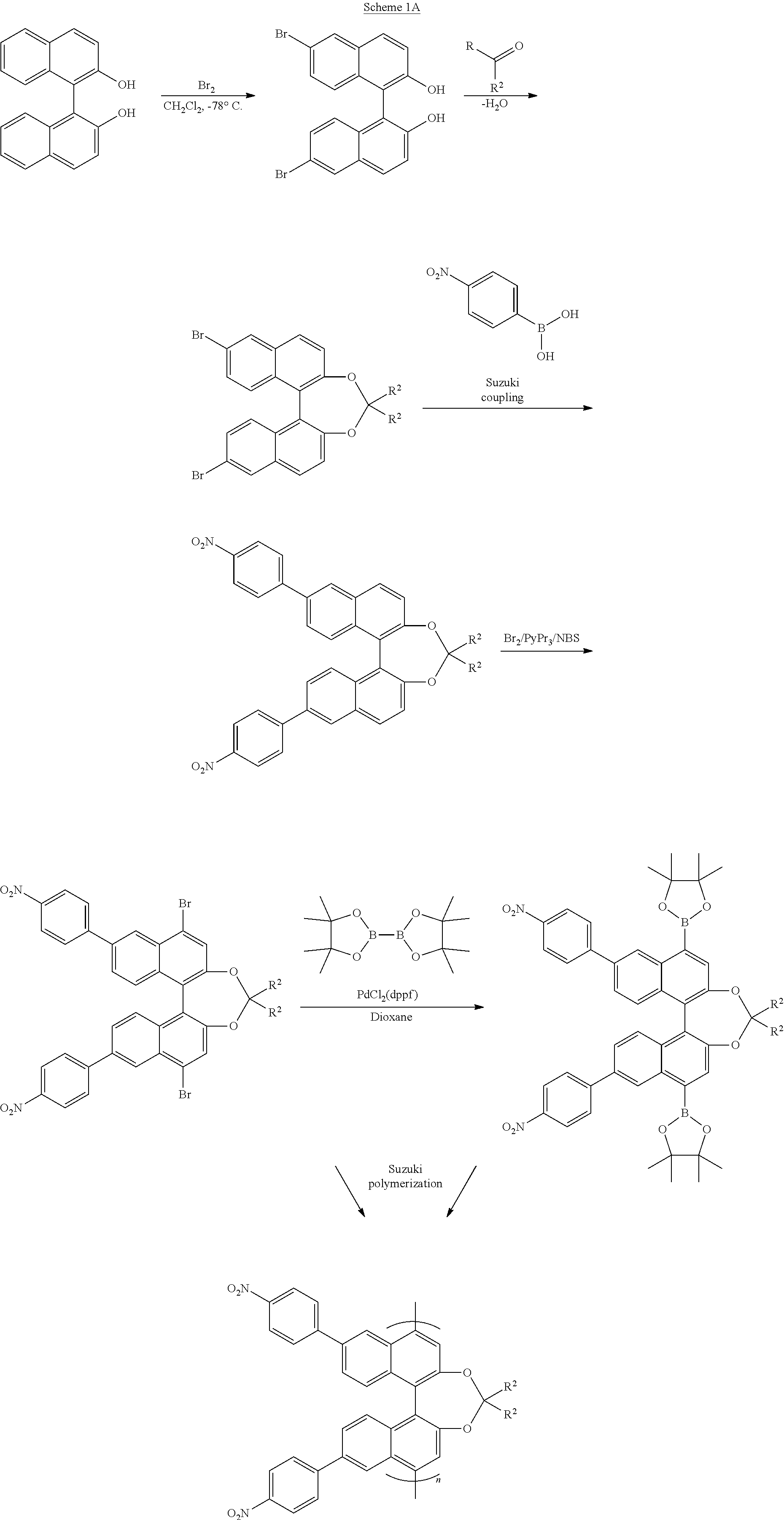

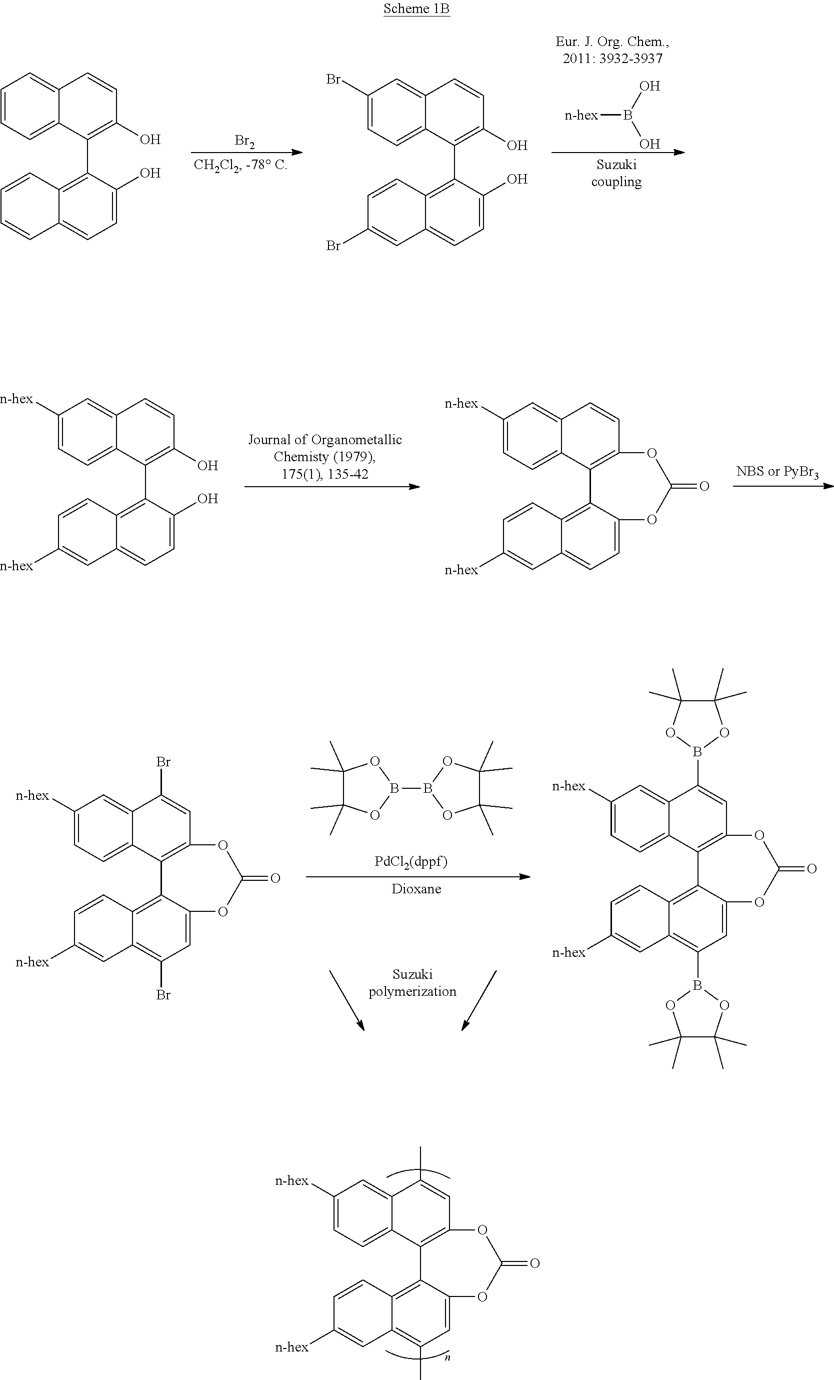

Exemplary syntheses of monomers and polymers containing a chiral biphenyl group are illustrated in schemes 2A-2C.

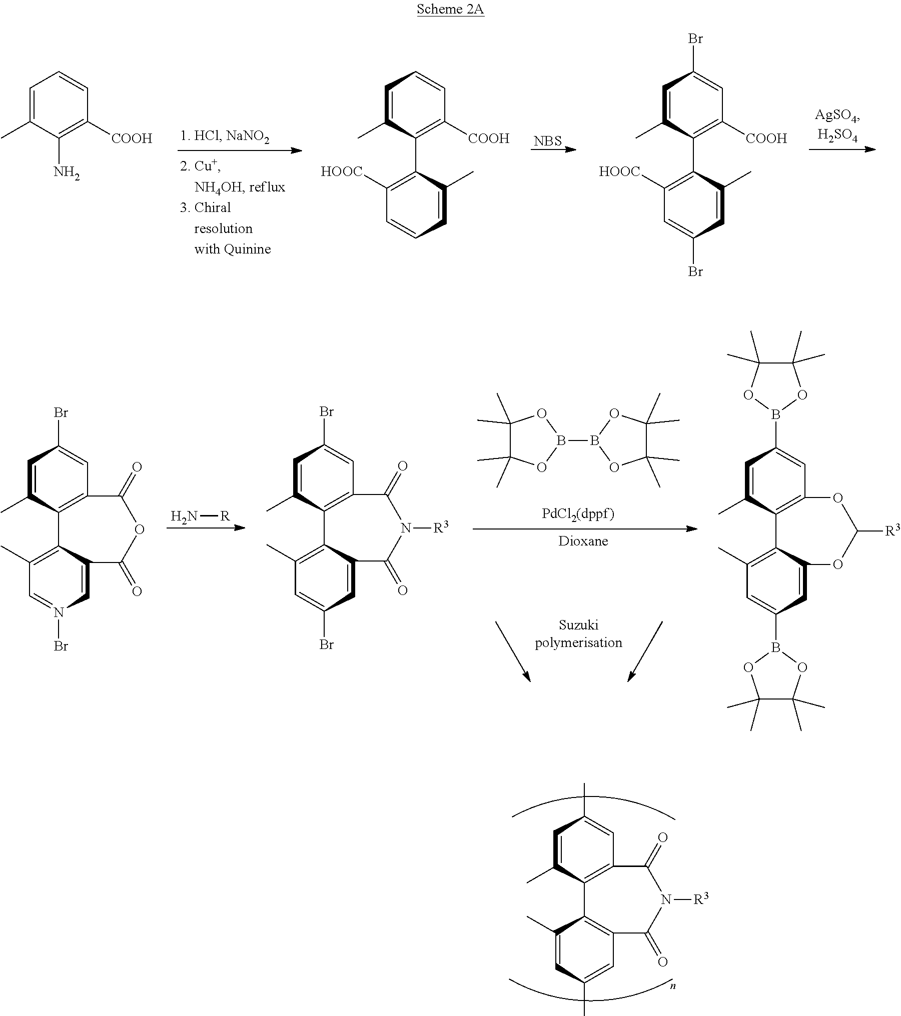

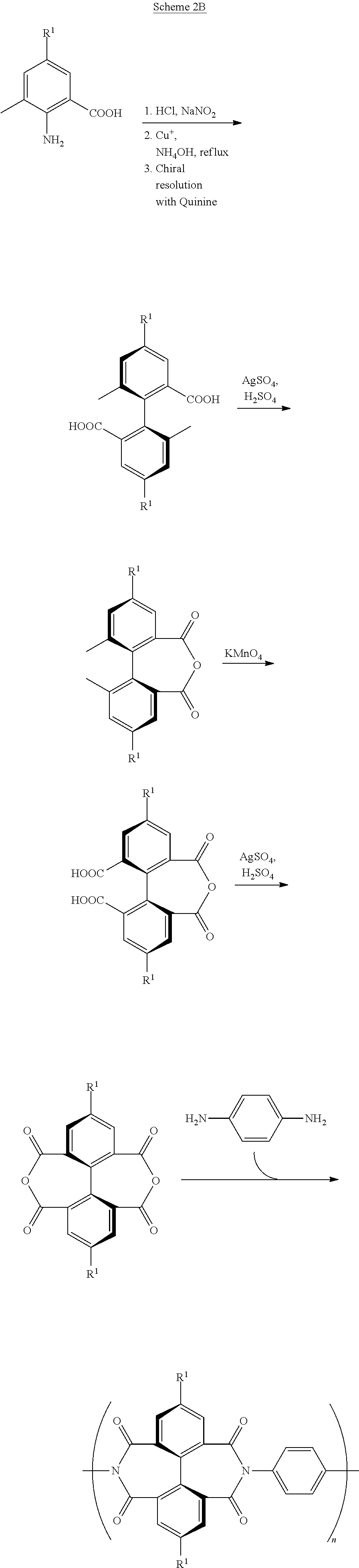

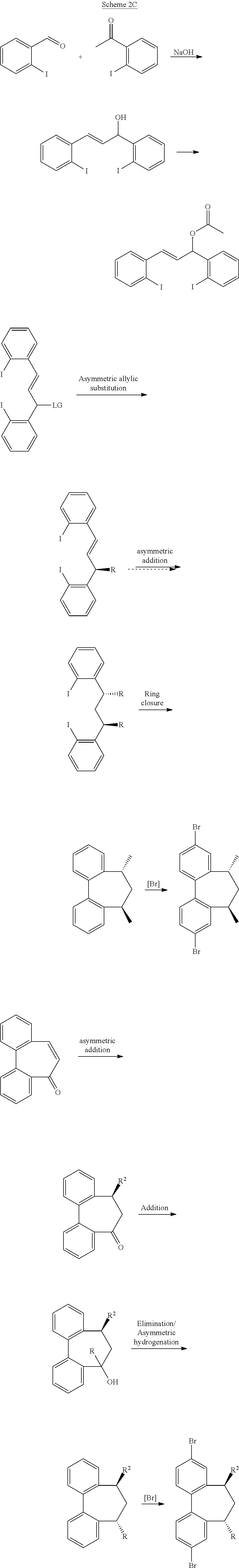

1. A chiral polymer comprising a repeat unit having a first planar group disposed in a first plane; a second planar group disposed in a second plane different from the first plane; a bond or group linking the first planar group and the second planar group; and a first divalent binding group linking the first planar group and the second planar group.

2. The polymer according to claim 1 wherein the repeat unit is bound to adjacent repeat units by first and second bonds and wherein the angle between the first and second bonds is 180°±10°.

3. The polymer according to claim 2 wherein the first and second bonds are collinear.

4. The polymer according to claim 1 wherein the repeat unit comprises a second divalent binding group.

5. The polymer according to claim 1 wherein the angle between the first plane and the second plane is in the range of 1-89°.

6. The polymer according to claim 1 wherein the first and second planar groups are, respectively, a first arylene or heteroarylene group and a second arylene or heteroarylene group and wherein each of the first and second arylene or heteroarylene groups is independently unsubstituted or substituted with one or more substituents.

7. The polymer according to claim 6 wherein the first and second arylene or heteroarylene groups are linked by a direct bond.

8. The polymer according to claim 7 wherein the direct bond is parallel to an axis of the polymer.

9. The polymer according to claim 7 wherein the direct bond is perpendicular to an axis of the polymer.

10. The polymer according to claim 1 wherein the repeat unit is selected from formulae (I)-(III): 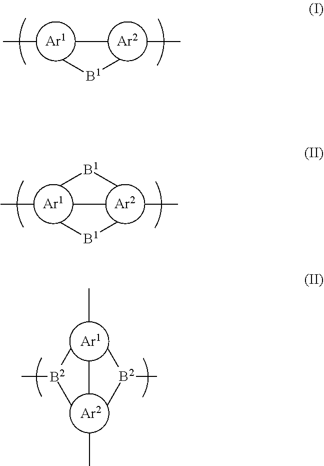
wherein Ar¹ is an arylene or heteroarylene group which is unsubstituted or substituted with one or more substituents; Ar² is an arylene or heteroarylene group which is unsubstituted or substituted with one or more substituents; B¹ in each occurrence is a divalent binding group and B² in each occurrence is independently a divalent binding group

11. The polymer according to claim 10 wherein the repeat unit is selected from formulae (Ia)-(IIIa):

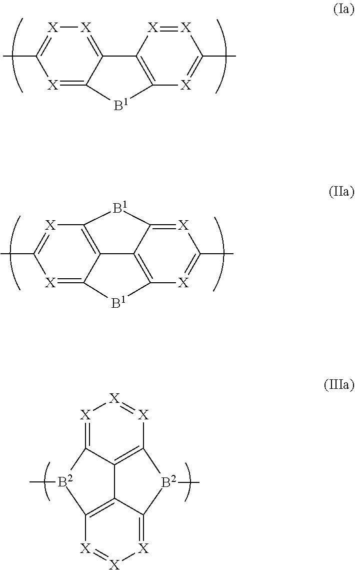

12. A chiral monomer of formula (I′) or (II′) or (III): 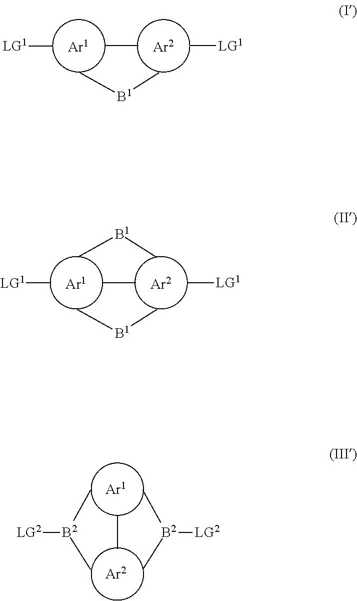
wherein Ar¹ is an arylene or heteroarylene group which is unsubstituted or substituted with one or more substituents and which is disposed in a first plane; Ar² is an arylene or heteroarylene group which is unsubstituted or substituted with one or more substituents and which is disposed in a second plane different from the first plane; B¹ in each occurrence is independently a divalent binding group; B² in each occurrence is independently a divalent binding group; LG¹ in each occurrence is independently a leaving group; and LG² in each occurrence is independently a leaving group.

13. The chiral monomer of claim 12 wherein LG¹ in each occurrence is a halide, pseudohalide or boronic acid or ester bound to an aromatic carbon atom of Ar¹ or Ar²; and LG² is H bound to an N atom of B².

14. A method of forming a polymer comprising polymerisation of a monomer according to claim 12.

15. An electrooptic modulator comprising a polymer film and electrodes for applying an electric field across the polymer film wherein the polymer film comprises a chiral polymer.

16. An electrooptic modulator comprising a polymer film and electrodes for applying an electric field across the polymer film wherein the polymer film comprises a chiral polymer wherein the chiral polymer is as defined in claim 1.

17. An optical interconnect for transmitting data, comprising:
the electrooptic modulator according to claim 15; and
a light source coupled to an input of the electrooptic modulator;
wherein the electrooptic modulator is configured to modulate light emitted by the light source.

18. The optical interconnect according to claim 17, further comprising an optical fibre coupled at a first end to an output of the electrooptic modulator to receive the modulated light.

19. The optical interconnect according to claim 18, further comprising a photodetector coupled to a second end of the optical fibre.

20. A system comprising:
the optical interconnect according to claim 17;
a first device; and
a second device;
wherein the optical interconnect is configured to transmit data from the first device to the second device.

21. The system according to claim 20, further comprising a second optical interconnect comprising an electrooptic modulator comprising a polymer film and electrodes for applying an electric field across the polymer film wherein the polymer film comprises a chiral polymer and a light source coupled to an input of the electrooptic modulator, wherein the electrooptic modulator is configured to modulate light emitted by the light source, the second optical interconnect being configured to transmit data from the second device to the first device.
